(19) United States
(12) Patent Application Publication
(10) Pub. No.: US 2013/0081679 A1
(43) Pub. Date: Apr. 4, 2013

(54) MULTIJUNCTION HYBRID SOLAR CELL INCORPORATING VERTICALLY-ALIGNED SILICON NANOWIRES WITH THIN FILMS

(71) Applicants: Jun Qu, Oakridge, TN (US); Theodore M. Besmann, Oak Ridge, TN (US); Sheng Dai, Knoxville, TN (US); Xiaoguang Zhang, Oakridge, TN (US)

(72) Inventors: Jun Qu, Oakridge, TN (US); Theodore M. Besmann, Oak Ridge, TN (US); Sheng Dai, Knoxville, TN (US); Xiaoguang Zhang, Oakridge, TN (US)

(73) Assignee: UT-BATTELLE, LLC, Oakridge, TN (US)

(21) Appl. No.: 13/250,044

(22) Filed: Sep. 30, 2011

(51) Int. Cl. H01L 31/0352; B82Y 99/00; B82Y 40/00

(52) U.S. Cl. 136/255; 438/87; 977/762; 257/E31.037; 977/948

(57) ABSTRACT

A low-cost method is provided for forming a photovoltaic device, which is a high-performance nanostructured multijunction cell. The multiple P-N junctions or P-I-N junctions are contiguously joined to form a single contiguous P-N junction or a single contiguous P-I-N junction. The photovoltaic device integrates vertically-aligned semiconductor nanowires including a doped semiconductor material with a thin silicon layer having an opposite type of doping. This novel hybrid cell can provide a higher efficiency than conventional photovoltaic devices through the combination of the enhanced photon absorptance, reduced contact resistance, and short carrier transport paths in the nanowires. Room temperature processes or low temperature processes such as plasma-enhanced chemical vapor deposition (PECVD) and electrochemical processes can be employed for fabrication of this photovoltaic device in a low-cost, scalable, and energy-efficient manner.

### CROSS REFERENCE TO RELATED APPLICATION

This application claims benefit from U.S. Provisional application Ser. No. 12/907,476, filed Oct. 19, 2010 the entire content and disclosure of which is incorporated herein by reference.

### STATEMENT REGARDING FEDERALLY SPONSORED RESEARCH OR DEVELOPMENT

This invention was made with government support under Contract No. DE-AC05-00OR22725 awarded by the U.S. Department of Energy. The government has certain rights in this invention.

### FIELD OF THE INVENTION

The present invention relates to a photovoltaic device, and particularly to a photovoltaic device including semiconductor nanowires, and methods of manufacturing the same.

### BACKGROUND OF THE INVENTION

The majority of solar photovoltaic modules are silicon-based. Conventional solar cells are single junction devices in which the junction extends over a large planar region and formed in a high qualify single crystalline silicon substrate. Fabrication of such solar cells requires high production costs and energy inputs. In contrast, photovoltaic devices can be formed at a substantially reduced production cost by employing a thin amorphous silicon film deposited over a large area at a low temperature or even room temperature via plasma enhanced physical vapor deposition (PECVD).

Silicon nanowire solar cells recently proposed have shown promising photovoltaic properties. However, the low absorptance for low-frequency photons, high series resistance, high production cost, and vulnerability to damage that are prevalent in the silicon nanowire solar cells have severely limited their applicability so far. Specifically, thin film silicon cells have much lower energy conversion efficiencies compared to bulk silicon cells due to the presence of dangling and twisted bonds in the amorphous silicon.

Coaxial silicon nanowire p-n junctions have recently emerged with promising enhancements in photovoltaic properties. These enhancements include high carrier-collection efficiency due to short transport distances, high optical absorptance for medium- to high-frequency photon energy, and very low reflectance. According to L. Hu and G. Chen, “Analysis of Optical Absorption in Silicon Nanowire Arrays for Photovoltaic Applications,” Nano Lett., 7(11) (2007) 3249-3252, the optical absorptance for coaxial silicon nanowires can be greater than 0.95, which is significantly higher than optical absorptance about 0.4-0.6 for conventional thin films, and the reflectance for the coaxial silicon nanowires can be less than 0.1, which is significantly less than the reflectance about 0.4-0.6 for the conventional thin films. High-aspect-ratio nanowires allow the use of a sufficient thickness of material to obtain good optical absorption while simultaneously providing short collection lengths for excited carriers in a direction normal to the light absorption. The short collection lengths facilitate the efficient collection of photogenerated carriers in materials with low minority-carrier diffusion lengths.

Modeling studies have indicated that a photovoltaic device employing a coaxial p-n junction cell may potentially provide large improvements in efficiency relative to a conventional photovoltaic device employing a planar geometry p-n junction cell. However, experimentally observed values for energy conversion efficiency of silicon nanowire solar cells range from 0.1% to 3.4%, which is much lower than theoretical values that range from 15% to 18%. One reason for this discrepancy may be the limited absorptance of low-frequency photons as reported by L. Hu and G. Chen. This discrepancy is believed to be mainly caused by high series resistance and low shunt resistance of the nanowires in the coaxial p-n junction cell. See L. Tsakalakos, J. Balch, J. Fronheiser, B. A. Korevaar, “Silicon nanowire solar cells,” Applied Physics Letters, 91 (2007) 233117. The contact resistance can be particularly high for the coaxial silicon nanowire configuration because both the core and shell are connected with the current collectors on their “tiny” ends yielding a very small contact area.

Current techniques for synthesizing silicon nanowires employ metallic catalysts via vapor-liquid-solid (VLS) process, pulsed laser deposition (PLD), and chemical vapor deposition (CVD) in high vacuum and at elevated temperatures in the range from 600° C. to 800° C. Metallic nanoparticles such as gold nanoparticles are usually used as catalysts. However, the metallic nanoparticles are potential contaminants resulting in increased carrier recombination within the wires impairing cell performance. In addition, the nanowires produced are usually not aligned well. Further, the minimal contact area with the substrate makes the conventional nanowires vulnerable to pull-off by mechanical stress, e.g., wind and vibration, and/or thermomechanical stress, e.g., mismatch of thermal expansion coefficients between silicon nanowires and substrate, experienced in actual operation environments.

### SUMMARY OF THE INVENTION

A low-cost method is provided for forming a photovoltaic device, which is a high-performance nanostructured multijunction cell. The multiple P-N junctions or P-I-N junctions are contiguously joined to form a single contiguous P-N junction or a single contiguous P-I-N junction. The photovoltaic device integrates vertically-aligned semiconductor nanowires including a doped semiconductor material with a thin silicon layer having an opposite type of doping. This novel hybrid cell can provide a higher efficiency than conventional photovoltaic devices through the combination of the enhanced photon absorptance, reduced contact resistance, and short carrier transport paths in the nanowires. Room temperature processes or low temperature processes such as plasma-enhanced chemical vapor deposition (PECVD) and electrochemical processes can be employed for fabrication of this photovoltaic device in a low-cost, scalable, and energy-efficient manner.

According to an aspect of the present invention, a method of forming a photovoltaic structure is provided. The method includes: providing a substrate including a silicon layer having a first conductivity type doping; forming an array of nanopores in the silicon layer by anodization; and forming a nanowire-including structure by depositing at least a doped semiconductor material having a second conductivity type in the array of nanopores, wherein the nanowire-including structure includes an array of nanowires filling the array of nanopores and a doped semiconductor layer, the doped semiconductor layer is attached to the array of nanowires and includes at least a portion of the doped semiconductor material, and the second conductivity type is the opposite of the first conductivity type.

According to another aspect of the present invention, a photovoltaic structure is provided, which includes: a silicon layer having a first conductivity type doping; and a nanowire-including structure including at least a doped semiconductor material having a second conductivity type, wherein the nanowire-including structure includes an array of nanowires and a doped semiconductor layer, the array of nanowires is embedded in the silicon layer, the doped semiconductor layer is attached to the array of nanowires and includes at least a portion of the doped semiconductor material, and the second conductivity type is the opposite of the first conductivity type.

### BRIEF DESCRIPTION OF THE DRAWINGS

FIG. 1 is a schematic view of a first exemplary structure including a silicon layer having a doping of a first conductivity type according to a first embodiment of the present disclosure.

FIG. 2 is a schematic view of the first exemplary structure after formation of nanopores in the silicon layer according to the first embodiment of the present disclosure.

FIG. 3 is a magnified view of a nanopore in FIG. 2.

FIG. 4 is a scanning electron micrograph (SEM) of a cleaved porous single-crystalline silicon material as known in prior art.

FIG. 5 is a schematic view of the first exemplary structure after formation of a nanowire-including structure containing a doped semiconductor material having a doping of a second conductivity type according to the first embodiment of the present disclosure.

FIG. 6 is a magnified view of a nanowire in FIG. 5.

FIG. 7 is a schematic view of the first exemplary structure after formation of a second conductive material layer according to the first embodiment of the present disclosure.

FIG. 8 is a schematic view of a second exemplary structure after formation of an intrinsic semiconductor material layer according to a second embodiment of the present disclosure.

FIG. 9 is a schematic view of the second exemplary structure after formation of a nanowire-including structure containing a doped semiconductor material having a doping of the second conductivity type and the intrinsic semiconductor material according to the second embodiment of the present disclosure.

FIG. 10 is a magnified view of a nanowire in FIG. 9.

FIG. 11 is a schematic view of the second exemplary structure after formation of a second conductive plate according to the second embodiment of the present disclosure.

FIG. 12 is a graph illustrating voltage profiles along a nanowire axis for cylindrical and conical nanowires.

FIG. 13 is a graph showing the results of a simulation for the electrostatic potential of a nanowire as a function of wire geometry

### DETAILED DESCRIPTION OF THE INVENTION

As stated above, the present invention relates to a photovoltaic device including semiconductor nanowires, and methods of manufacturing the same, which are now described in detail with accompanying figures. It is noted that like and corresponding elements mentioned herein and illustrated in the drawings are referred to by like reference numerals. It is also noted that proportions of various elements in the accompanying figures are not drawn to scale to enable clear illustration of elements having smaller dimensions relative to other elements having larger dimensions.

As used herein, “room temperature” refers to a temperature in a range from 15° C. to 40° C.

As used herein, a “nanopore” is a pore that has a lateral dimension that does not exceed 1,000 nm.

As used herein, a “nanowire” is a structure that has a lengthwise dimension along a lengthwise direction, wherein the lengthwise dimension is at least an order of magnitude greater than a maximum lateral dimension in directions perpendicular to the lengthwise direction, and the maximum lateral dimension does not exceed 1,000 nm.

As used herein, a “nanothread” is a nanowire that does not include any laterally protruding structures in any direction that is different from a lengthwise direction.

As used herein, a direction is “substantially vertical” if the direction deviates from a vertical direction by no more than 2 degrees.

A first element is “substantially perpendicular” to a second element if the angle between the first element and the second element is between 88 degrees and 92 degrees.

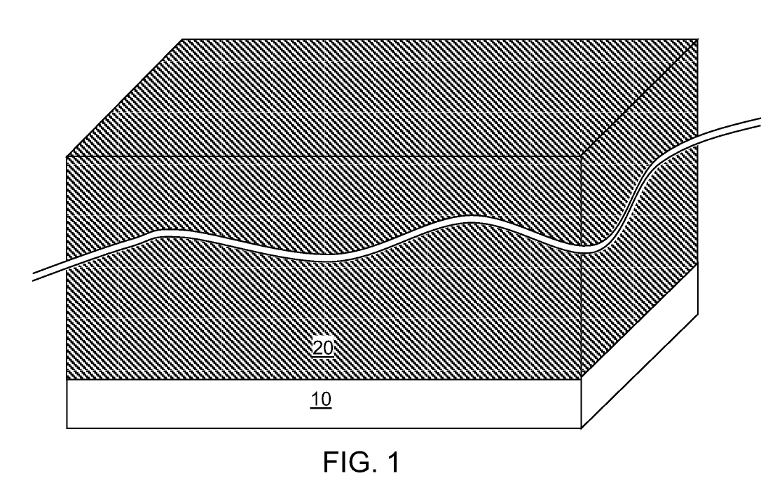

A unique photovoltaic structure includes a hybrid nanostructured multijunction photovoltaic device, which combines a thin planar semiconductor film structure with vertically-aligned semiconductor nanowires. The hybrid nanostructured multijunction photovoltaic device includes a P-N junction or a P-I-N junction on a surface of the thin planar semiconductor film and a plurality of P-N junctions or a plurality of P-I-N junctions on surfaces of the vertically-aligned semiconductor nanowires. All P-N junctions in the hybrid nanostructured multijunction photovoltaic device are contiguously connected to one another to constitute a single contiguous P-N junction or a single contiguous P-I-N junction. This photovoltaic structure substantially enhances energy conversion efficiency above the energy conversion efficiency of either a thin film solar cell or a nanowires cell. This photovoltaic structure can be fabricated at relatively low cost. A non-limiting exemplary method of forming this photovoltaic structure is illustrated by the schematic views illustrated in FIGS. 1, 2, 3, 5, 6, 7, 8, 9, 10, and 11.

Referring to FIG. 1, a first exemplary structure according to a first embodiment of the present disclosure includes a substrate, which includes a silicon layer 20 having a first conductivity type and a first conductive material layer 10. The substrate can consist of a stack of the first conductive material layer 10 and the silicon layer 20, or can further include at least another layer located at the bottom of the first conductive material layer 10 such as a dielectric substrate (such as a glass substrate or any other dielectric substrate) or another conductive material layer. For example, the first conductive material layer 10 can be a metallic layer including a metallic material. The metallic material can be aluminum, copper, or any other elemental metal or a conductive metallic alloy. The first conductive material layer 10 is a first conductive plate that functions as a first electrode of a photovoltaic device to be formed.

The silicon layer 20 includes silicon and at least one dopant having the first conductivity type. The first conductivity type can be p-type or n-type. P-doped silicon material can be formed by doping silicon with a p-type dopant such as B, Al, Ga, and/or In. N-doped silicon material can be formed by doping silicon with an n-type dopant such as P, As, and/or Sb. The silicon layer 20 can have the same constant thickness throughout.

In one embodiment, the silicon layer 20 can include amorphous or polycrystalline hydrogenated silicon having a doping of the first conductivity type, which can be deposited, for example, by plasma enhanced chemical vapor deposition (PECVD), low temperature chemical vapor deposition (LPCVD), physical vapor deposition (PVD, i.e., sputtering), or by any other suitable deposition methods known in the art. In this embodiment, hydrogen-containing ambient is employed during deposition of the silicon layer 20 so that hydrogen is included in the silicon layer. Hydrogen present in an amorphous or polycrystalline hydrogenated silicon film has the effect of passivating dangling bonds of silicon atoms, and de-localizing the electronic states caused by the dangling bonds of the silicon atoms, thereby enhancing the conductivity of the amorphous or polycrystalline hydrogenated silicon film over an amorphous or polycrystalline silicon film without hydrogen. The silicon layer 20 can be deposited directly on the conductive metal layer 10 so that the conductive metal layer 10 contacts the silicon layer 20. The thickness of the silicon layer 20 can be from 1 micron to 1,000 microns, although lesser and greater thicknesses can also be employed. In a non-limiting illustrative example, the silicon layer 20 can include an n-type amorphous silicon thin film including phosphorus as n-type dopants and be deposited on a metal plate including aluminum or stainless steel by PECVD. A silicon-containing reactant gas such as SiH₄ and an n-type dopant gas such as PH₃ can be employed for the PECVD process. Because plasma provides energy to the reactant gas and the dopant gas, it is generally unnecessary to elevate the temperature of the metal plate to deposit the silicon layer 20. In case a PECVD process is employed to form the silicon layer 20, the process parameters for the PECVD process can be tailored to achieve the desired film thickness and dopant concentration for the silicon layer 20.

In another embodiment, the silicon layer 20 can include single crystalline silicon. The silicon layer 20 can have any crystallographic orientation. In one case, the silicon layer 20 can have one of the major crystallographic orientations along which formation of nanapores is accelerated during anodization. The stack of the first conductive material layer 10 and the silicon layer 20 can be formed by depositing the first conductive material layer 10 on a substrate including the silicon layer 20 that includes single crystalline silicon having a doping of the first conductivity type, or can be formed by transferring the silicon layer 20 that includes single crystalline silicon having a doping of the first conductivity type, for example, by wafer bonding. The thickness of the silicon layer 20 can be from 1 micron to 1,000 microns, although lesser and greater thicknesses can also be employed.

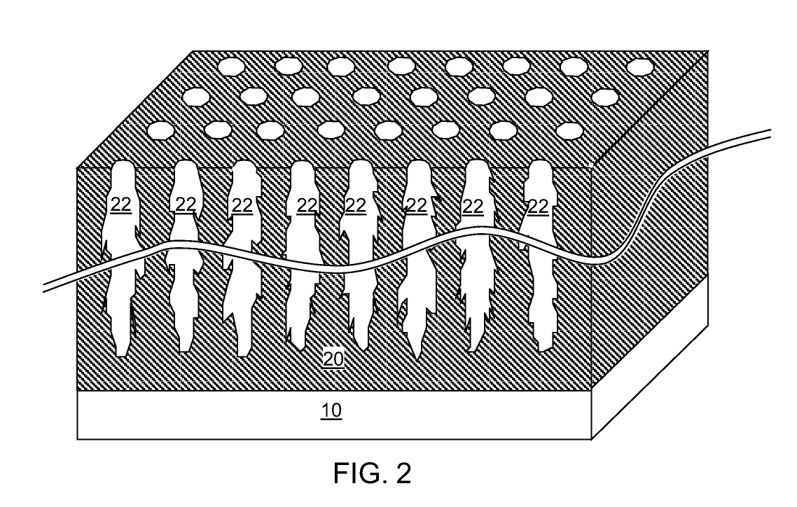

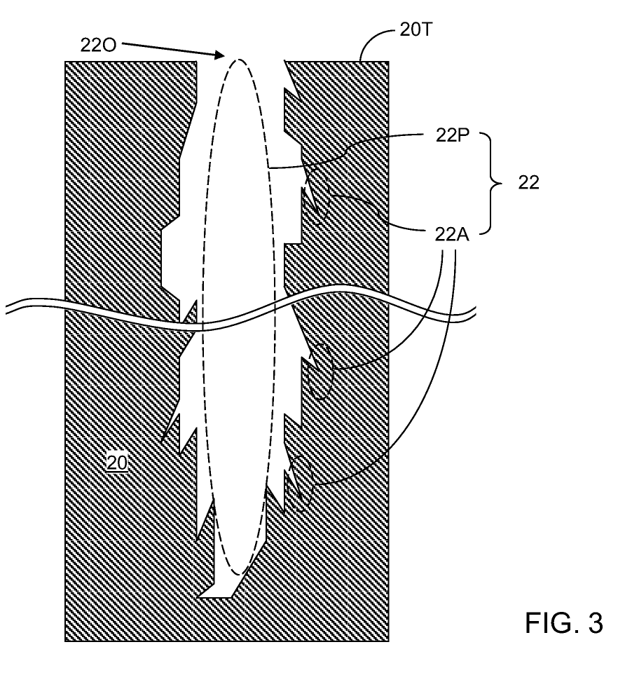

Referring to FIGS. 2 and 3, an array of nanopores 22 is formed in the silicon layer 20 by anodization. It is known that an array of nanopores 22 can be formed in a silicon layer by anodization. Specifically, the nanopores 22 can be formed with vertical alignment in the silicon layer 20 by an electrochemical anodization process in a HF-containing solution under suitable conditions. The anodization process for producing vertically aligned nanopores in the silicon layer 20 is an etch process. As such, the anodization process requires a specific match among processing parameters, i.e., among the HF-concentration in an aqueous etchant, the dopant concentration in the silicon layer 20, and the current density during the anodization process, in order to form the vertically aligned nanopores successfully.

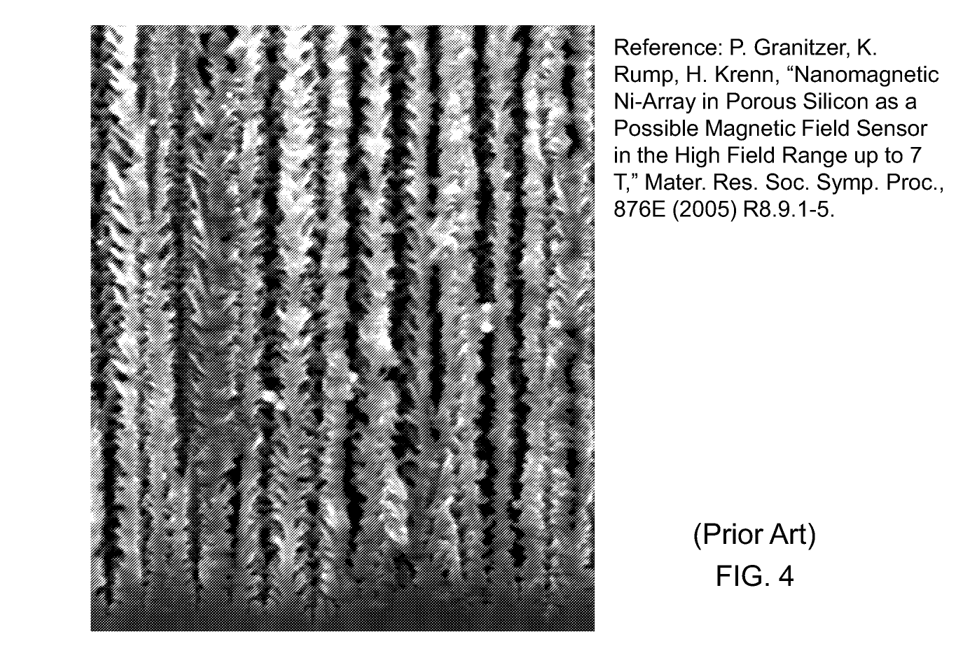

Referring to FIG. 4, a scanning electron micrograph (SEM) of a cleaved porous n-doped single crystalline silicon sample is shown as reported in P. Granitzer, K. Rump, and H. Krenn, “Nanomagnetic Ni-Array in Porous Silicon as a Possible Magnetic Field Sensor in the High Field Range up to 7 T,” Mater. Res. Soc. Symp. Proc., 876E (2005) R8.9.1-5. The array of nanopores can have a “fir tree” configuration, which includes a primary trench and a plurality of ancillary trenches extruding from the primary trench. The primary trench extends from the top to the bottom of each nanopore, and each of the ancillary trenches extends a short distance and typically has a smaller lateral dimension than the primary trench. The ancillary trenches extend a distance that is less than 1/10, and typically less than 1/100, of the length of the primary trench.

Referring back to FIGS. 2 and 3, the silicon layer 20 as anodized can include nanopores 22 with porosity ranging from about 30% to about 80%, i.e., the volume of the nanopores can be from about 30% to 80% of the original volume of silicon before anodization. Depending on the conditions employed for anodization and the crystalline structure of the silicon layer 20, the nanopores can be branched and exhibit a very characteristic “fir tree” configuration known in the art. In general, structures having high porosity can be formed employing a single crystalline silicon layer. Further, the silicon layer 20 can be heat-treated after formation of the nanopores 22 to induce significant migration of silicon atoms and to substantially increase feature sizes as needed. For example, the lateral dimensions of the nanopores 22 can be increased up to 1,000 nm if desired.

In general, the nanopores 22 can have a fir tree configuration, in which each nanopore 22 includes a primary trench 22P and a plurality of ancillary trenches 22A extruding from the primary trench 22P. The ancillary trenches 22 are also referred to as “side pockets,” and have a length that is at least one order of magnitude less than the depth of a nanopore 22, i.e., the length of the primary trench 22P in the nanopore 22. Typically, ancillary trenches 22 have a length that is at least two orders of magnitude less than the depth of the nanopore 22. The silicon layer 20 has a planar top surface 20T from which the array of nanopores 22 extends into the silicon layer 20.

The distal ends, i.e., the pointy ends that do not adjoin a primary trench 22P, of the plurality of ancillary trenches 22A generally point away from the opening 220 of the primary trench 22P. As used herein, first elements “generally” points away from a second element if more than 90% of the first elements point away from the second element. The lengthwise direction of each nanopore 22 can be substantially vertical. Thus, the lengthwise direction of a primary trench 22P therein can be substantially perpendicular to the planar top surface 20T of the silicon layer 20.

In general, the anodization process can be performed in an aqueous hydrofluoric acid, and nanopores 22 in the array of nanopores are laterally spaced from one another. The nanopores 22 in the array of nanopores can have a vertical dimension from 1 micron to 100 micron, although lesser and greater vertical dimensions can also be employed. The nanopores 22 in the array of nanopores can have a maximum lateral dimension from 5 nm to 1,000 nm, although lesser and greater maximum lateral dimensions can also be employed. The depth of the nanopores 22 depends on the etching time, i.e., the duration of the anodization process, and can be from 1 micron to 1,000 microns.

In a non-limiting illustrative example, an n-type hydrogen-containing amorphous silicon film can be employed for the silicon layer 20, which is anodized in an aqueous HF acid solution to generate a high-density array of vertically-aligned nanopores. The nanopores 22 extend vertically into the silicon layer 20, but does not reach the first conductive material layer 10 so that a P-N junction or a P-I-N junction to be subsequently formed is not electrically shorted to the first conductive material layer 10. Fabrication of a high aspect-ratio self-aligned nanopore, with a pore diameter from 10 nm to 60 nm and a pore depth of 10 micron to 30 microns, has been demonstrated for a highly doped n-type silicon wafer in P. Granitzer, K. Rump, and H. Krenn.

Wide ranges of porosity and pore depth can be reproducibly obtained employing anodization under galvanostatic conditions, which effects etching of the silicon material in the silicon layer 20. Layer microstructure is sensitive to many etching parameters which need to be controlled during the anodization process. The etching parameters include not only electrolyte composition, current density and applied potential, and the temperature of the electrolyte bath. In some embodiments, ethanol can be frequently added to the hydrofluoric acid to minimize hydrogen bubble formation during anodization, and thereby to improve thickness uniformity in thickness.

In general, porous silicon can be formed by electrolytic anodization in a solution containing HF. An HF-resistant electrode, such as one made of platinum, is biased negatively, and a substrate including amorphous, microcrystalline, or single-crystalline silicon is biased positively. The porosity, measured in terms of the mass loss, of the resulting porous silicon layer is typically proportional to the electrical current density and inversely proportional to the HF concentration. The depth of the resulting porous silicon layer formed within a region of silicon can be proportional to the anodization time for a given dopant concentration and current density. The actual structure of the porous silicon material, however, depends on the type and concentration of dopants and defects, in addition to the above-mentioned parameters. A common characteristic of porous silicon materials is the enormous surface area associated with high-density pores. The total surface area per unit volume in a porous silicon material is estimated to be 100-200 m²/cm³, i.e., 100-200 square meters of surface area per each cubic centimeter in volume.

In a non-limiting illustrative example of values for the etching parameters, the concentration of the hydrofluoric acid solution can be about 10% in weight percentage, the current density can be about 100 mA/cm², the dopant concentration in the silicon layer 20 can be from about 10¹⁶/cm³ to about 10²⁰/cm³. The porous silicon structure in the silicon layer 20 can be tailored with different morphologies. For dopant concentrations greater than 10¹⁷/cm³, the growth mechanism of the nanopores is controlled by a charge transfer through band-to-band tunneling of charge carriers across the space charge region. The porous silicon structure can include highly oriented nanopores in a rectangular array, which is a different arrangement from honeycomb structures of pores formed in anodic alumina.

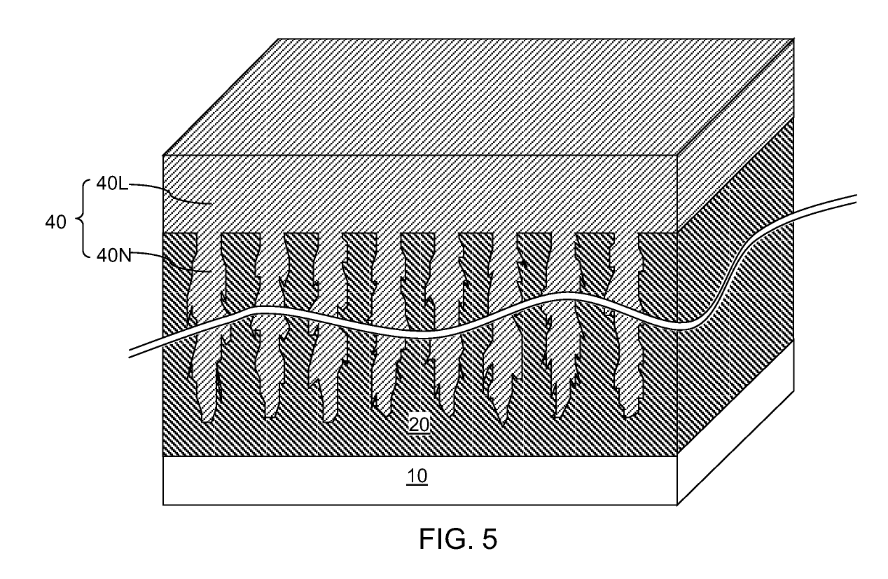

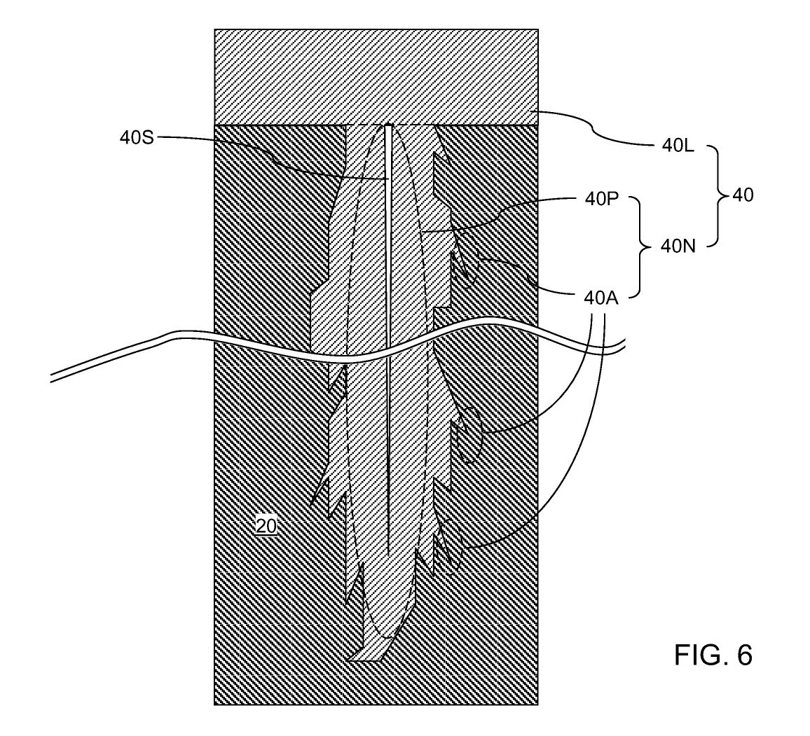

Referring to FIGS. 5 and 6, a nanowire-including structure is formed by depositing a doped semiconductor material in the array of nanopores 22 and on the planar top surface 20T of the silicon layer 20. The nanowire-including structure is an integral assembly, i.e., an assembly of a single contiguous construction, of a doped semiconductor layer 40L and an array of nanowires 40N. The doped semiconductor material layer 40L is planar and has the same thickness throughout. As such, the doped semiconductor material layer 40L is a planar doped semiconductor portion having a constant thickness. The integral assembly of the doped semiconductor layer 40L and the array of nanowires 40N is herein referred to as a doped nanowire-including structure 40, which constitutes the entirety of the nanowire-including structure.

The doped semiconductor material has a doping of a second conductivity type, which is the opposite of the first conductivity type. For example, if the first conductivity type is p-type, the second conductivity type is n-type, and vice versa. Thus, if the silicon layer 20 is a p-doped silicon layer, the doped nanowire-including structure 40 is n-doped, and vice versa. The dopant concentration of the doped nanowire-including structure 40 can be from 1.0×10¹⁶/cm³ to 1.0×10²⁰/cm³, although lesser and greater concentrations can also be employed.

The array of nanowires 40N fills the array of nanopores 22 (See FIGS. 2 and 3) and includes portions of the deposited doped semiconductor material. The doped semiconductor layer 40L is attached to the array of nanowires and includes another portion of the doped semiconductor material. Because the array of nanowires 40N and the doped semiconductor layer 40L are formed simultaneously in a same deposition process, the array of nanowires 40N and the doped semiconductor layer 40L have the same composition. The doped semiconductor material can be amorphous or polycrystalline, and has a doping of the second conductivity type, i.e., includes dopant atoms having the second conductivity type. The doped semiconductor material of the doped nanowire-including structure 40 can include silicon, germanium, a silicon-containing alloy that may contain carbon or germanium, a germanium-containing alloy that may contain carbon or silicon, and/or a compound semiconductor material. The doped semiconductor material can be a hydrogenated semiconductor material in which the hydrogen atoms reduce the dangling bonds of semiconductor atoms therein.

If the array of nanopores 22 (See FIGS. 2 and 3) has a fir tree configuration, the array of nanowires 40N filling the array of nanopores 22 also has a fir tree configuration. As such, the array of nanowires 40N includes a primary nanothread 40P and a plurality of ancillary nanothreads 40A extruding from the primary nanothread 40P. The array of nanowires 40N extends from interface between the silicon layer 20 and the doped semiconductor layer 40L the into the silicon layer 20. The interface between the silicon layer 20 and the doped semiconductor layer 40L is the same as the planar top surface 20T of the silicon layer 20. Distal ends of the plurality of ancillary nanothreads 40A generally point away from the interface between the silicon layer 20 and the doped semiconductor layer 40L.

In one embodiment, the doped semiconductor layer 40L and the array of nanowires 40N can be deposited by an electrodeposition process employing a non-aqueous solvent, a semiconductor-element-containing electrolyte dissolved in the non-aqueous solvent, and a dopant-containing electrolyte dissolved in the non-aqueous solvent. 19. The non-aqueous solvent can be an ionic liquid. Chemistry for the electrodeposition can be selected to deposit the doped semiconductor layer 40L and the array of nanowires 40N at room temperature, although electrodeposition processes at temperatures higher or lower than the room temperature can also be employed. The doped semiconductor material is deposited directly on surfaces of the array of nanopores 22 in the silicon layer 20 and directly on the planar top surface 20T of the silicon layer 20.

In a non-limiting illustrative example, a doped semiconductor material can be electrodeposited in the array of nanopores 22 and on the planar top surface 20T of the silicon layer 20. As discussed above, the doped semiconductor material is p-doped if the silicon layer is n-doped, and vice versa. Electrodeposition of the doped silicon material can be effected at room temperature employing ionic liquid electrolytes. Ionic liquids are composed solely of cations and anions, and yet are liquids at room temperature. Ionic liquids can offer a large electrochemical window to enable the electrodeposition of silicon. It is noted that electrodeposition of silicon is not possible in conventional aqueous solutions because of hydrogen evolution from electrolysis of water.

Electrodeposition of silicon in an ionic liquid containing SiCl₄ or GeCl₄ has been successfully demonstrated using polycarbonate (PC) membranes in R. Al-Salman et al., “Template assisted electrodeposition of germanium and silicon nanowires in an ionic liquid,” Phys. Chem. Chem. Phys., 10 (2008) 6233-6237. In this case, the potentiostatic electrochemical deposition of germanium or silicon nanowires was demonstrated employing an ionic liquid, which was 1-butyl-1-methylpyrrolidinium bis(trifluoromethylsulfonyl)imide ([Py1,4]Tf2N). The ionic liquid contained GeCl₄ or SiCl₄ as solutes, and commercially available track-etched polycarbonate membranes (a non-semiconductor material) having a nominal pore diameter from 90 nm to 400 nm were used as templates. A deposition rate for amorphous silicon was estimated to be about 2-3 microns per hour in R. Al-Salman et al.

In a non-limiting illustrative example, the doped semiconductor material can be p-doped silicon, p-doped germanium, or a p-doped silicon-germanium alloy, and the silicon layer 20 can have an n-type doping. In this case, the array of nanowires 40N includes p-type silicon nanowires, which grow inside the array of nanopores 22 located in the silicon layer 20, which is an n-type film. The growth of the array of nanowires 40N can be effected by electrodeposition in an ionic liquid electrolyte dissolving a silicon salt such as SiCl₄ and a dopant source such as AlCl₃. The ionic liquid employed for the non-aqueous solvent can be 1-butyl-1-methylpyrrolidinium bis(trifluoromethylsulfonyl)imide. The semiconductor-element-containing ionic liquid electrolyte can include at least one of SiCl₄ and GeCl₄. The dopant-containing electrolyte can be AlCl₃. The species for the semiconductor-element-containing ionic liquid electrolyte and the dopant-containing electrolyte may be replaced with appropriate substitute electrolytes to provide a doped semiconductor material including a different semiconductor material and/or a different p-type or n-type dopant.

The electrodeposition method of the present disclosure provides an enhanced deposition rate compared with the method of R. Al-Salman et al. Since the p-type silicon material is deposited simultaneously on the bottom surfaces and sidewalls of the nanopores 22 in the silicon layer 20, the growth rate of the nanowires 40N according to the present disclosure is much greater than the growth rate of silicon or germanium in PC membranes as reported in R. Al-Salman et al., in which the growth proceeds only from the bottom surfaces of the PC membranes that act as a template. Further, because the bottom surfaces of the nanopores 22 have a shorter distance to the first conductive material layer 10 that functions as an electrode than the sidewalls of the nanopores 22, the bottom surfaces of the nanopores 22 are in the paths of the least electrical resistance during the electrodeposition process. Thus, the doped semiconductor material is deposited on the bottom surfaces of the nanopores 22 faster than elsewhere, e.g., sidewalls, thereby enabling a more nearly complete fill of each nanopore 22 with a minimal volume for seams 40S. Each nanowire 40N may include a seam 40S along the lengthwise direction of the nanowire 40N. The length of the seam 40S in each nanowire 40N is less than the entire length of the nanowire 40N, but differ from the entire length of the nanowire 40N only by a dimension on the order of the maximum lateral dimension of the nanowire 40N.

Further, the electrodeposition method of the present disclosure provides deposition of the doped semiconductor material directly on a semiconductor material, i.e., the semiconductor material on the surfaces of the nanopores 22 in the silicon layer 20 and the planar top surface 20T of the silicon layer 20. In contrast, the method of R. Al-Salman et al. deposits a silicon material on a dielectric surface, i.e., the surface of a polycarbonate matrix comprising a dielectric polymer.

At the end of the electrodeposition process, each nanopore 22 in the silicon layer 20 is filled with a semiconductor nanowire having a doping of the opposite type of doping as the silicon layer 20. Each region around an interface between a nanowire 40N and the silicon layer 20 forms a P-N junction. Because the nanowires 40N form a vertically aligned array in which the lengthwise direction of each nanowire 40N is substantially parallel to one another, an array of substantially vertical P-N junctions is formed across the silicon layer 20 and the array of nanowires 40N. Further, a planar P-N junction is formed at the planar interface between the planar top surface 20T of the silicon layer 20 and a planar bottom surface of the doped semiconductor layer 40L. The planar P-N junction and the array of substantially vertical P-N junctions around the array of nanowires 40N collectively constitute a single contiguous P-N junction. Thus, the contiguous P-N junction is formed between the silicon layer 20 and an assembly of the array of nanowires 40N and the doped semiconductor layer 40L. The array of nanowires 40N consists of portions of the doped semiconductor material having a doping of the second conductivity type.

In a non-limiting illustrative example, if a nanowire 40N has a maximum lateral dimension of about 50 nm and an adjacent pair of nanowires 40N is laterally spaced by a distance of about 100 nm, about 100 million substantially vertical P-N junctions are formed on a 1 mm² planar surface area. Thus, a high-density substantially vertical nanowire P-N junction array is embedded in the silicon layer 20. The substantially vertical nanowire P-N junction array has the benefit of decoupling the absorption of light from charge transport by allowing lateral diffusion of minority carriers to the substantially vertical P-N junctions, which are nanometers away rather than many microns away as in conventional silicon cells. This hybrid multijunction cell is also expected to combine the photon absorptance of the thin film (in the form of the doped semiconductor layer 40L and an upper portion of the silicon layer 20) and the photon absorptance of the array of nanowires 40N and the portions of the silicon layer 20 that laterally surround the array of nanowires 40N. Thus, the absorptance of the photovoltaic device employing the silicon layer 20 and the doped nanowire-including structure 40 is greater than the absorptance of a thin film solar cell or the absorptance of a solar cell employing only an array of nanowires.

The electrodeposition process of the present disclosure for depositing semiconductor nanowires inside an array of nanopores is a new process, and as such, requires a systematic designing and fine tuning of the process parameters to achieve fast uniform growth and avoid porosity in the semiconductor nanowire. A semiconductor material is deposited on all exposed semiconductor surfaces including the bottom surfaces and the sidewalls of the nanopores 22 as well as on the top planar surface of the silicon layer 20. Since the deposition rate is greater at a location with less potential drop (lower resistance), the growth of the semiconductor nanowires can be a bottom-up fill process that follows the electrical resistance profile. However, an imperfect geometry of nanopores may cause interrupts in the fill process, resulting in at least one seam 40S. For instance, a narrower section in the middle of a nanopore 22 may produce an early seal that traps unwanted electrolytes therein. Reducing the aspect ratio and/or creating conic shape nanopores (lesser lateral dimensions at the bottom of the nanopores) can alleviate this issue.

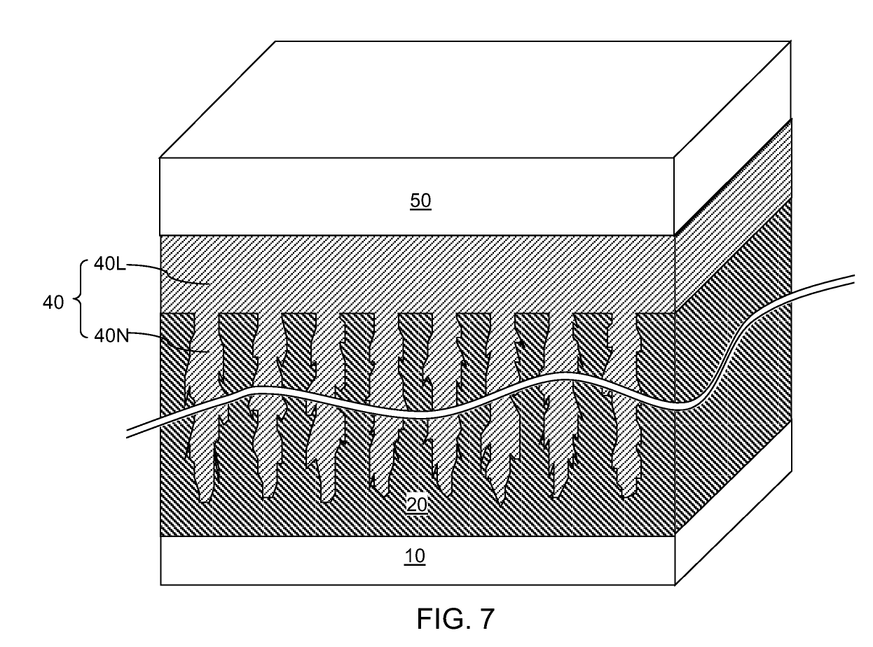

Referring to FIG. 7, a second conductive material layer 50 is formed on a planar top surface of the doped semiconductor layer 40L. In one embodiment, the second conductive material layer 50 can include a transparent conductive oxide material. Exemplary transparent conductive oxide materials include, but are not limited to, indium tin oxide (ITO) and zinc oxide. The second conductive material layer 50 is a second conductive plate that functions as a second electrode of the photovoltaic device of the present disclosure.

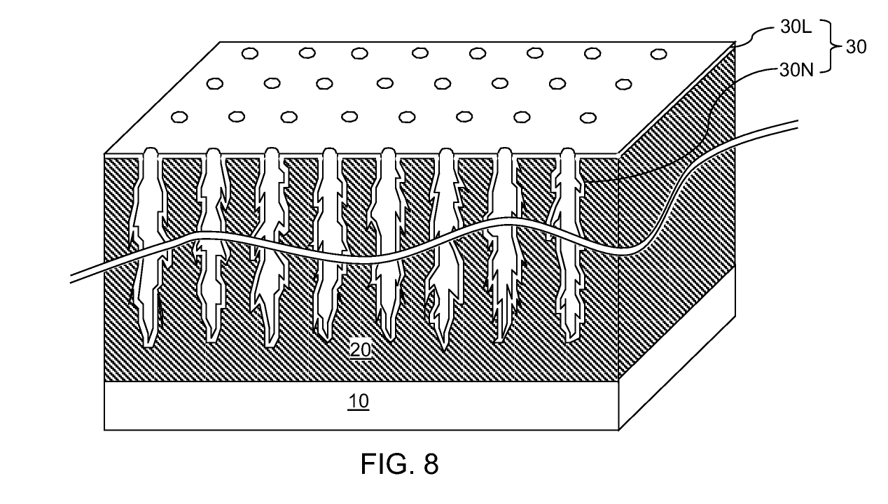

Referring to FIG. 8, a second exemplary structure according to a second embodiment of the present disclosure is derived from the first exemplary structure of FIGS. 2 and 2 A by depositing an intrinsic semiconductor material layer 30 directly on surfaces of the array of nanopores 22 and the planar top surface 20T of the silicon layer 20. The intrinsic semiconductor material layer 30 includes an intrinsic semiconductor material.

The intrinsic semiconductor material in the intrinsic semiconductor material layer can include silicon, germanium, a silicon-containing alloy that may contain carbon or germanium, a germanium-containing alloy that may contain carbon or silicon, and/or a compound semiconductor material. The intrinsic semiconductor material can be a hydrogenated semiconductor material in which the hydrogen atoms reduce the dangling bonds of semiconductor atoms therein.

The intrinsic semiconductor material layer 30 can be deposited by an electrodeposition process employing a non-aqueous solvent and the semiconductor-element-containing electrolyte without employing any dopant-containing electrolyte. For example, the non-aqueous solvent employed for electrodeposition of the intrinsic semiconductor material layer 30 can be the same as the non-aqueous solvent employed for electrodeposition of the doped nanowire-including structure 40 illustrated in FIGS. 5 and 6.

The intrinsic semiconductor material layer 30 is deposited as a single contiguous layer without any hole therein. The intrinsic semiconductor material layer 30 includes an array of intrinsic nanowire shells 30N and a planar intrinsic semiconductor portion 30L. The array of intrinsic nanowire shells 30N include portions of the intrinsic semiconductor material layer 30 located within, and partially filling, the array of nanopores 22. The array of intrinsic nanowire shells 30N is located below a top planar surface 20T (See FIG. 3) of the silicon layer 20. The planar intrinsic semiconductor portion 30L is a planar portion of the intrinsic semiconductor material layer 30 and contacts the planar top surface 20T (See FIG. 3) of the silicon layer 20. The planar intrinsic semiconductor portion 30L has a constant thickness throughout. The thickness of the intrinsic semiconductor material layer 30 is less than half the nominal lateral dimension of each nanopore 22, so that the nanopores 22 are not filled by the intrinsic semiconductor material layer 30.

In a non-limiting exemplary illustration, the electrodeposition process to form the doped nanowire-including structure 40 at a processing step corresponding to FIGS. 5 and 6 in the first embodiment can be employed to form the intrinsic semiconductor material layer 30 provided that any dopant-containing electrolyte is removed from the electrodeposition chemistry and the processing time is shortened appropriately. The intrinsic semiconductor material layer 30 is deposited simultaneously on the bottom surfaces and sidewalls of the nanopores 22 and directly on the doped silicon material on all surfaces of the nanopores 22 in the silicon layer 20. The thickness of the intrinsic semiconductor material layer 30 can be from 5 nm to 100 nm, although lesser and greater thicknesses can also be employed.

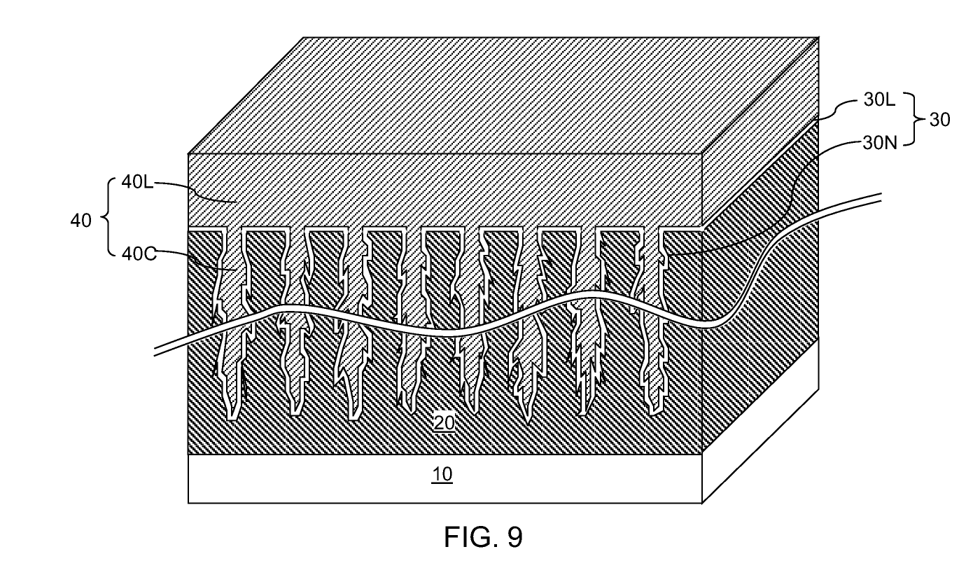

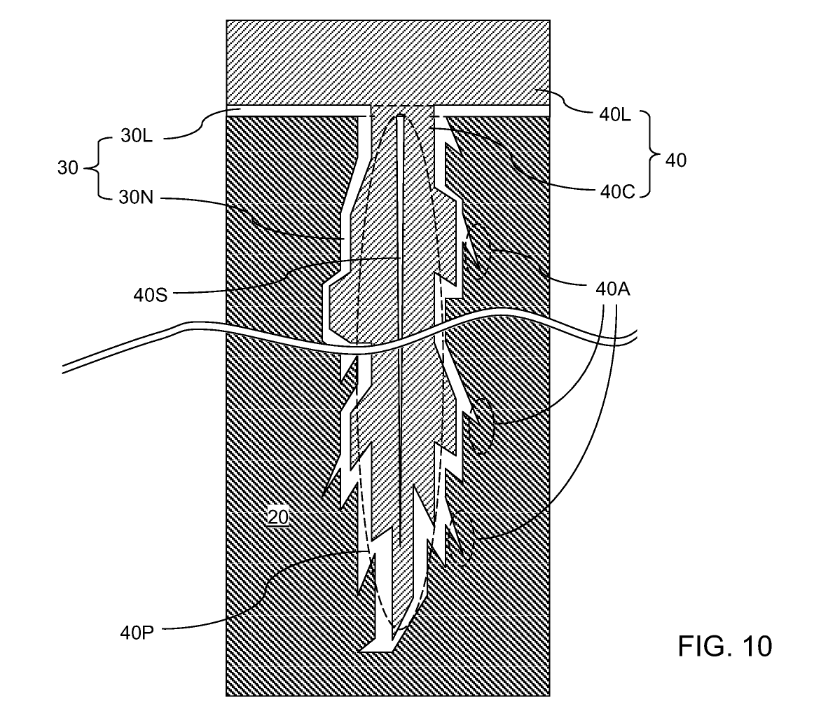

Referring to FIGS. 9 and 10, a doped semiconductor material is deposited employing the same processing step as the processing step of FIGS. 5 and 6 according to the first embodiment. In the second embodiment, the doped semiconductor material is deposited directly on exposed surfaces of the intrinsic semiconductor material layer 30. Further, the doped semiconductor material is deposited simultaneously on all exposed bottom surfaces and sidewalls of the intrinsic semiconductor material layer 30 in the nanopores 22.

The portions of the doped semiconductor material filling the array of nanopores 22 form an array of doped nanowire cores 40C. The planar portion of the doped semiconductor material located above the top surface of the planar intrinsic semiconductor portion 30L form a doped semiconductor layer 40L. A pair of a doped nanowire core 40C and an intrinsic nanowire shell 30N filling the same nanopore 22 collectively form a nanowire (40C, 30N). The stack of the planar intrinsic semiconductor portion 30L and the doped semiconductor layer 40L collectively form a planar semiconductor material stack having a constant total thickness.

A nanowire-including structure of the second embodiment includes an array of nanowires (40C, 30N), the planar intrinsic semiconductor portion 30L, and the doped semiconductor layer 40L. An array of doped nanowire cores 40C and the doped semiconductor layer 40L is of integral construction without any interface therein. An array of intrinsic nanowire shells and the planar intrinsic semiconductor portion 30L is of integral construction without any interface therein.

The array of nanowires (40C, 30N) fills the array of nanopores 22 (See FIGS. 2 and 3). Each nanowire (40C, 30N) includes a doped nanowire core 40C and an intrinsic nanowire shell 30N embedding and spacing the doped nanowire core 40C from the silicon layer 20. Because the array of doped nanowire cores 40C and the doped semiconductor layer 40L are formed simultaneously in a same deposition process, the array of doped nanowire cores 40C and the doped semiconductor layer 40L have the same composition. The doped semiconductor material can be amorphous or polycrystalline, and has a doping of the second conductivity type, i.e., includes dopant atoms having the second conductivity type. The doped semiconductor material of the array of doped nanowire cores 40C and the doped semiconductor layer 40L can include silicon, germanium, a silicon-containing alloy that may contain carbon or germanium, a germanium-containing alloy that may contain carbon or silicon, and/or a compound semiconductor material. The doped semiconductor material can be a hydrogenated semiconductor material in which the hydrogen atoms reduce the dangling bonds of semiconductor atoms therein. In general, the array of doped nanowire cores 40C and the doped semiconductor layer 40L of the second embodiment can have the same composition as the array of nanowires 40N and the doped semiconductor layer 40L of the first embodiment, and can be formed by employing the same processing step employed to form the array of nanowires 40N and the doped semiconductor layer 40L in the first embodiment.

If the array of nanopores 22 (See FIGS. 2 and 3) has a fir tree configuration, the array of nanowires (40C, 30N) filling the array of nanopores 22 also has a fir tree configuration. As such, the array of nanowires (40C, 30N) includes a primary nanothread 40P and a plurality of ancillary nanothreads 40A extruding from the primary nanothread 40P. A primary nanothread 40P includes most of a doped nanowire core 40C and a significant portion of an intrinsic nanowire shell 30N filling a same nanopore 22. An ancillary nanothread 40A typically includes only a portion of the intrinsic nanowire shell 30N, although the ancillary nanothread 40A may include a portion of the doped nanowire core 40C in some cases (if the size of an ancillary trench 22A is significant; See FIG. 3). The array of nanowires (40C, 30N) extends from interface between the silicon layer 20 and the planar intrinsic semiconductor portion 30L the into the silicon layer 20. The interface between the silicon layer 20 and the planar intrinsic semiconductor portion 30L is the same as the planar top surface 20T of the silicon layer 20. Distal ends of the plurality of ancillary nanothreads 40A generally point away from the interface between the silicon layer 20 and the planar intrinsic semiconductor portion 30L.

Since a doped semiconductor material is deposited simultaneously on the bottom surfaces and sidewalls of the intrinsic nanowire shell 30N within each nanopore 22, the growth rate of the doped nanowire cores 40C according to the present disclosure is much greater than the growth rate of silicon or germanium in PC membranes as reported in R. Al-Salman et al., in which the growth proceeds only from the bottom surfaces of the PC membranes that act as a template. Further, because the bottom surfaces of the intrinsic nanowire shell 30N have a shorter distance to the first conductive material layer 10 that functions as an electrode than sidewalls of the intrinsic nanowire shell 30N, the bottom surfaces of the intrinsic nanowire shell 30N are in the paths of the least electrical resistance during the electrodeposition process. Thus, the doped semiconductor material is deposited on the bottom surfaces of the intrinsic nanowire shell 30N faster than elsewhere, thereby enabling a more nearly complete fill of each nanopore 22 with a minimal volume for seams 40S. Each doped nanowire cores 40C may include a seam 40S along the lengthwise direction of the doped nanowire cores 40C. The length of the seam 40S in each doped nanowire cores 40C is less than the entire length of the doped nanowire cores 40C, but differ from the entire length of the doped nanowire cores 40C only by a dimension on the order of the maximum lateral dimension of the doped nanowire cores 40C.

The electrodeposition method employed to form the array of doped nanowire cores 40C and the doped semiconductor layer 40L provides deposition of the doped semiconductor material directly on a semiconductor material, i.e., the semiconductor material on the surfaces of the intrinsic semiconductor material layer 30. Ionic liquid-based electrolytes with unique large electrochemical windows may offer more flexibility in terms of selecting the size, the spacing, and the depth of the nanopores 22 during the anodization process illustrated in FIGS. 2 and 3.

At the end of the electrodeposition process, each nanopore 22 in the silicon layer 20 is filled with a semiconductor nanowire having a doping of the opposite type of doping as the silicon layer 20. Each nanowire (40C, 30N) in the array of nanowires includes a doped nanowire core 40C embedded in an intrinsic nanowire shell 30N. The doped nanowire core 40C includes the doped semiconductor material, and the intrinsic nanowire shell 30N includes the intrinsic semiconductor material. Each region around an interface between a nanowire (40C, 30N) and the silicon layer 20 forms a P-I-N junction. Because the nanowires (40C, 30N) form a vertically aligned array in which the lengthwise direction of each nanowire (40C, 30N) is substantially parallel to one another, an array of substantially vertical P-I-N junctions is formed across the silicon layer 20 and the array of nanowires (40C, 30N). Further, a planar P-I-N junction is formed across all portions of the planar intrinsic semiconductor portion 30L. The planar P-I-N junction and the array of substantially vertical P-I-N junctions around the array of nanowires (40C, 30N) collectively constitute a single contiguous P-I-N junction. Thus, the contiguous P-I-N junction is formed between the silicon layer 20 and an assembly of the array of nanowires (40C, 30N) and the doped semiconductor layer 40L. The array of nanowires (40C, 30N) includes portions of the doped semiconductor material having a doping of the second conductivity type, i.e., the array of the doped nanowire cores 40C, and portions of the intrinsic semiconductor material, i.e., the array of the intrinsic nanowire shells 30N. The intrinsic semiconductor layer 30 forms the intrinsic portion of the contiguous P-I-N junction.

In a non-limiting illustrative example, if a nanowire (40C, 30N) has a maximum lateral dimension of about 50 nm and an adjacent pair of nanowires (40C, 30N) is laterally spaced by a distance of about 100 nm, about 100 million substantially vertical P-I-N junctions are formed on a 1 mm² planar surface area. Thus, a high-density substantially vertical nanowire P-I-N junction array is embedded in the silicon layer 20. The substantially vertical nanowire P-I-N junction array has the benefit of decoupling the absorption of light from charge transport by allowing lateral diffusion of minority carriers to the substantially vertical P-I-N junctions, which are nanometers away rather than many microns away as in conventional silicon cells. As in the first embodiment, the hybrid multijunction cell of the second embodiment is also expected to combine the photon absorptance of the thin film (in the form of the doped semiconductor layer 40L, the planar intrinsic semiconductor portion 30L, and an upper portion of the silicon layer 20) and the photon absorptance of the array of nanowires (40C, 30N) and the portions of the silicon layer 20 that laterally surround the array of nanowires (40C, 30N).

The processing steps of the FIG. 8 and FIGS. 9 and 10 can be integrated into a single electrodeposition step, in which a dopant electrolyte is added to the non-aqueous solution at the beginning of the electrodepositon of the doped semiconductor material, i.e., at the beginning of the processing step corresponding to FIGS. 9 and 10. In other words, a semiconductor material can be electrodeposited without a dopant for a first period of time to form the intrinsic semiconductor layer 30 in the outer portion of the nanopores 22, followed by filling of the nanopores 22 with the doped semiconductor material. The thickness of the intrinsic semiconductor layer 30 can be adjusted by controlling the timing of the addition of a dopant-containing electrolyte.

The addition of the intrinsic semiconductor layer 30 between the silicon layer 20 having a doping of the first conductivity type and the doped semiconductor material having a doping of the second conductivity type can enhance the performance of the photovoltaic device.

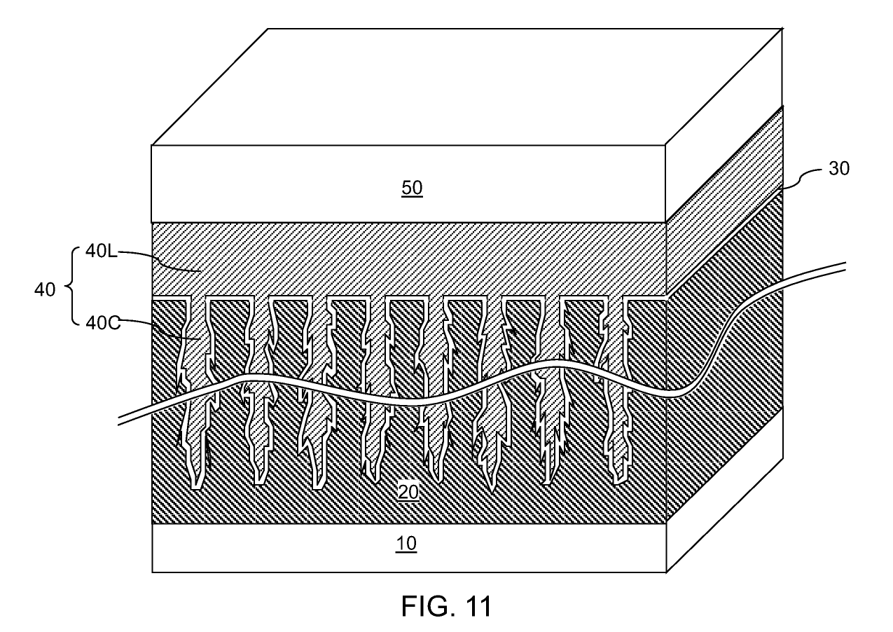

Referring to FIG. 11, a second conductive material layer 50 can be formed employing the same processing step as in FIG. 7 of the first embodiment.

In general, the hybrid photovoltaic device of the present disclosure can eliminate or reduce the high contact resistance problem for prior art photovoltaic devices that employ nanowires directly grown on an electrode. In the hybrid photovoltaic device of the present disclosure, semiconductor nanowires (i.e., nanowires 40N in the first embodiment or nanowires (40C, 30N) in the second embodiment) do not directly connect any electrode, but are integrated with the doped semiconductor layer 40L. The large contact area between the silicon layer 20 and the first electrode, i.e., the first conductive material layer 10 provide low contact resistance on one side. The large contact area between the doped semiconductor layer 40L and the second electrode, i.e., the second conductive material layer 50 provide low contact resistance on the other side.

Performance of the hybrid photovoltaic device of the present disclosure can be enhanced by optimizing the dimensional parameters of semiconductor nanowires (i.e., nanowires 40N in the first embodiment or nanowires (40C, 30N) in the second embodiment). Such dimensional parameters include the maximum lateral dimension (e.g., diameter), the length, and the spacing of the semiconductor nanowires, the dopant concentrations in the silicon layer 10 and the doped semiconductor material of the doped semiconductor layer 40L, and the thickness of the intrinsic semiconductor layer 30 in the second embodiment. In general, longer nanowires and thicker semiconductor layers tend to absorb more photon energy, but also increase manufacturing cost because of increased usage of semiconductor material(s) and longer processing time. Dopant concentrations in semiconductor nanowires (i.e., nanowires 40N in the first embodiment or nanowires (40C, 30N) in the second embodiment) must be sufficiently high so that the semiconductor nanowires are not fully depleted. For example, doped silicon having a dopant concentration of about 1.0×10¹⁸/cm³ yield a depletion width of about 50 nm, which corresponds to a maximum lateral dimension of about 100 nm. To avoid local shunting across the semiconductor nanowires due to imperfect wire geometry, a semiconductor nanowire having a slightly greater maximum lateral dimension may be used. Use of a higher dopant concentration for the doped portion of the semiconductor nanowires can enable a lesser maximum lateral dimension for the semiconductor nanowire.

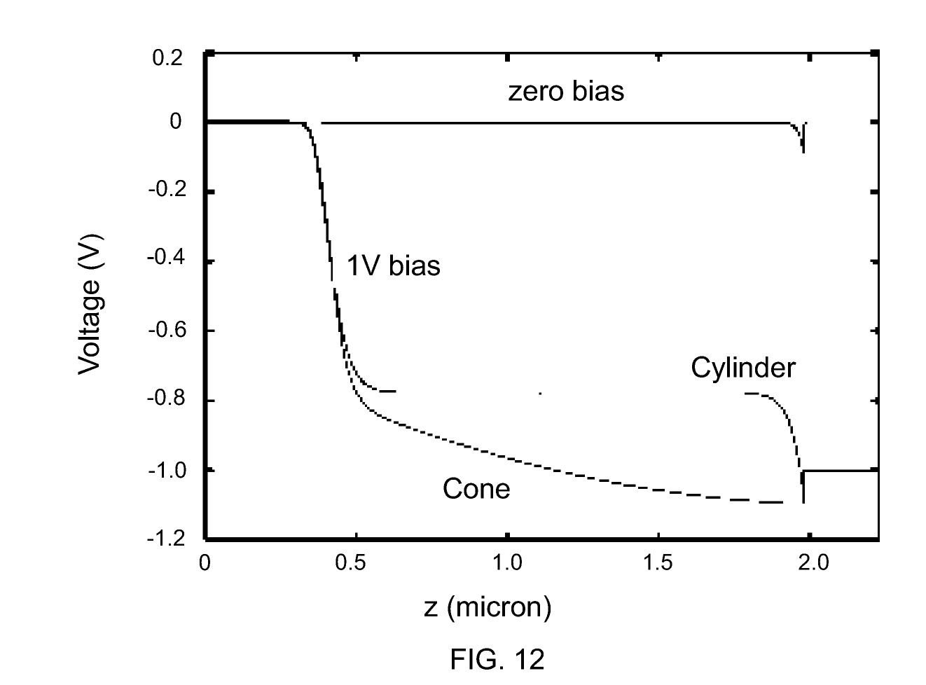

One factor that can help improve carrier transport characteristics is the electric field strength along the length of the wire. Referring to FIG. 12, a preliminary study on this subject suggests that the field strength depends sensitively on the dimension and the geometric shape of the semiconductor nanowire. In particular, a long, straight semiconductor nanowire does not have homogeneous electric field along the length of the wire. The voltage drop occurs mostly at the two ends of the semiconductor nanowire. This is a disadvantage for carrier collection. In contrast, a cone-shaped nanostructure produces a more uniform electric field along its axis, leading to better carrier collection efficiency. The geometric parameters of the semiconductor nanowire can be optimized to enhance carrier transport and to improve the energy conversion efficiency.

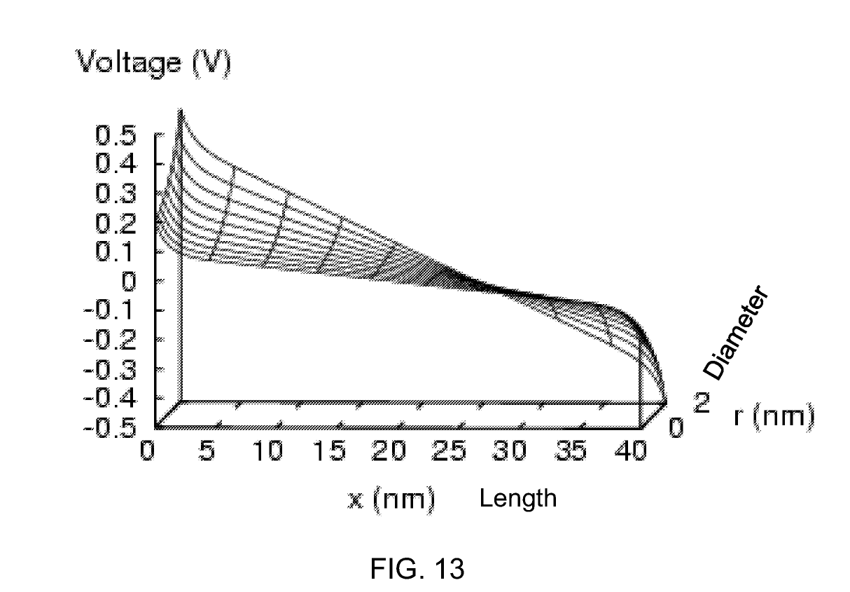

The electronic structure of the semiconductor material, the dopant concentration level, the operating temperature, and applied electrical bias affect the carrier density in the photovoltaic device of the present disclosure. Referring to FIG. 13, a preliminary work on this subject demonstrates that when the diameter of the semiconductor nanowire is comparable to the Debye length, the electric field along the length of the semiconductor nanowire cannot be completely screened even if the length of the semiconductor nanowire is much longer than the Debye length.

The photovoltaic device of the present disclosure provides high energy conversion efficiency by combining the photon absorptance of thin film and nanowires and by taking advantage of very short carrier transport paths and a self-aligned one-dimensional structure of a high-density P-N junction or P-I-N junction array. The density of substantially vertical junctions can be from 1.0×10⁷/mm² to 1.0×10⁹/mm². The high contact resistance issue in prior art semiconductor nanowires is eliminated or significantly alleviated by avoiding direct contacts between the semiconductor nanowires and the electrode.

Further, the photovoltaic device of the present disclosure provides a robust and reliable nanostructure, in which semiconductor nanowires are embedded in a mechanically supportive thin film matrix, i.e., the silicon layer 20.

Further, the photovoltaic device of the present disclosure can be manufactured employing inexpensive and scalable processes. Specifically, the processes employed to manufacture the photovoltaic device of the present disclosure can employ a low-temperature PECVD process for deposition of the silicon layer 20 and electrochemical processes without involving high temperatures or metal catalysts (potential contaminants) as required in prior art methods for forming semiconductor nanowires. The high carrier-collection efficiency of nanowire P-N or P-I-N junctions allows the use of lower-quality semiconductor material for the semiconductor nanowires of the present disclosure.

The disclosed method for manufacturing the photovoltaic device is versatile and flexible, and is applicable to large surface areas. Thus, deposition can be made on foils or non-planar surfaces, i.e., curved surfaces having a finite radius of curvature. Thus, the method of the present disclosure can be employed to roll-to-roll processing techniques, and is suitable for complex geometries.

In addition to photovoltaic applications, the hybrid nanostructure of the present disclosure can also be employed for other types of energy harvesting, conversion, and storage applications, such as batteries and thermoelectric devices.

While the invention has been described in terms of specific embodiments, it is evident in view of the foregoing description that numerous alternatives, modifications and variations will be apparent to those skilled in the art. Accordingly, the invention is intended to encompass all such alternatives, modifications and variations which fall within the scope and spirit of the invention and the following claims.

What is claimed is:

1. A method of forming a photovoltaic structure comprising:
providing a substrate including a silicon layer having a first conductivity type doping;
forming an array of nanopores in said silicon layer by anodization; and
forming a nanowire-including structure by depositing at least a doped semiconductor material having a second conductivity type in said array of nanopores, wherein said nanowire-including structure comprises an array of nanowires filling said array of nanopores and a doped semiconductor layer, said doped semiconductor layer is attached to said array of nanowires and comprises at least a portion of said doped semiconductor material, and said second conductivity type is the opposite of said first conductivity type.

2. The method of claim 1, wherein each nanowire in said array of nanowires includes a primary nanothread and a plurality of ancillary nanothreads extruding from said primary nanothread.

3. The method of claim 2, wherein said silicon layer has a planar top surface from which said array of nanowires extends into said silicon layer.

4. The method of claim 3, wherein distal ends of said plurality of ancillary nanothreads generally point away from said planar top surface.

5. The method of claim 1, wherein each nanopore in said array of nanopores includes a primary trench and a plurality of ancillary trenches extruding from said primary trench.

6. The method of claim 5, wherein said silicon layer has a planar top surface from which said array of nanopores extends into said silicon layer.

7. The method of claim 6, wherein distal ends of said plurality of ancillary trenches generally point away from said planar top surface.

8. The method of claim 1, wherein said array of nanowires consists of portions of said doped semiconductor material.

9. The method of claim 8, wherein a contiguous P-N junction is formed between said silicon layer and an assembly of said array of nanowires and said doped semiconductor layer.

10. The method of claim 1, further comprising depositing an intrinsic semiconductor layer comprising an intrinsic semiconductor material on surfaces of said array of nanopores, wherein said doped semiconductor layer is deposited on surfaces of said intrinsic semiconductor layer.

11. The method of claim 10, wherein each nanowire in said array of nanowires includes a doped nanowire core embedded in an intrinsic nanowire shell, wherein said doped nanowire core comprises said doped semiconductor material and said intrinsic nanowire shell comprises said intrinsic semiconductor material.

12. The method of claim 10, wherein a contiguous P-I-N junction is formed between said silicon layer and an assembly of said array of nanowires and said doped semiconductor layer, wherein said intrinsic semiconductor layer forms an intrinsic portion of said contiguous P-I-N junction.

13. The method of claim 1, wherein said anodization is performed in an aqueous hydrofluoric acid, and nanopores in said array of nanopores are laterally spaced from one another.

14. The method of claim 13, wherein nanopores in said array of nanopores have a vertical dimension from 1 micron to 100 micron.

15. The method of claim 14, wherein nanopores in said array of nanopores have a maximum lateral dimension from 5 nm to 1,000 nm.

16. The method of claim 1, wherein said doped semiconductor material is deposited by an electrodeposition process employing a non-aqueous solvent, a semiconductor-element-containing electrolyte dissolved in said non-aqueous solvent, and a dopant-containing electrolyte dissolved in said non-aqueous solvent.

17. The method of claim 16, wherein said dopant-containing electrolyte includes AlCl₃.

18. The method of claim 16, wherein said semiconductor-element-containing ionic liquid electrolyte includes at least one of SiCl₄ and GeCl₄.

19. The method of claim 16, wherein said non-aqueous solvent is an ionic liquid.

20. The method of claim 19, wherein said ionic liquid is 1-butyl-1-methylpyrrolidinium bis(trifluoromethylsulfonyl)imide.

21. The method of claim 16, wherein chemistry for said electrodeposition is selected to deposit said doped semiconductor material at room temperature.

22. The method of claim 16, wherein said doped semiconductor material is deposited directly on surfaces of said silicon layer in said array of nanopores.

23. The method of claim 16, further comprising depositing an intrinsic semiconductor layer comprising an intrinsic semiconductor material directly on surfaces of said silicon layer in said array of nanopores by another electrodeposition process employing said non-aqueous solvent and said semiconductor-element-containing electrolyte and not employing any dopant-containing electrolyte.

24. The method of claim 23, wherein said other electrodeposition process is performed prior to said electrodeposition process.

25. The method of claim 1, wherein said silicon layer includes amorphous hydrogenated silicon or polycrystalline hydrogenated silicon.

26. The method of claim 25, wherein said silicon layer is deposited directly on a conductive metal layer.

27. The method of claim 1, wherein said silicon layer includes single crystalline silicon.

28. The method of claim 1, further comprising forming a conductive material layer on a surface of said doped semiconductor layer.

29. The method of claim 28, wherein said conductive material layer includes a transparent conductive oxide material.

30. A photovoltaic structure comprising:
a silicon layer having a first conductivity type doping; and
a nanowire-including structure comprising at least a doped semiconductor material having a second conductivity type, wherein said nanowire-including structure comprises an array of nanowires and a doped semiconductor layer, said array of nanowires is embedded in said silicon layer, said doped semiconductor layer is attached to said array of nanowires and comprises at least a portion of said doped semiconductor material, and said second conductivity type is the opposite of said first conductivity type.

31. The photovoltaic structure of claim 30, wherein each nanowire in said array of nanowires includes a primary nanothread and a plurality of ancillary nanothreads extruding from said primary nanothread.

32. The photovoltaic structure of claim 31, wherein said silicon layer has a planar top surface from which said array of nanowires extends into said silicon layer.

33. The photovoltaic structure of claim 32, wherein distal ends of said plurality of ancillary nanothreads generally point away from said planar top surface.

34. The photovoltaic structure of claim 30, wherein said array of nanowires consists of portions of said doped semiconductor material.

35. The photovoltaic structure of claim 34, wherein a contiguous P-N junction is present between said silicon layer and an assembly of said array of nanowires and said doped semiconductor layer.

36. The photovoltaic structure of claim 30, further comprising an intrinsic semiconductor layer comprising an intrinsic semiconductor material and including a planar intrinsic semiconductor portion and a plurality of intrinsic nanowire shells, wherein said planar intrinsic semiconductor portion contacts a planar surface of said silicon layer and each nanowire in said array of nanowires includes one of said plurality of intrinsic nanowire shells.

37. The photovoltaic structure of claim 36, wherein each nanowire in said array of nanowires includes a doped nanowire core embedded in an intrinsic nanowire shell, wherein said doped nanowire core comprises said doped semiconductor material and said intrinsic nanowire shell comprises said intrinsic semiconductor material.

38. The photovoltaic structure of claim 36, wherein a contiguous P-I-N junction is present between said silicon layer and an assembly of said array of nanowires and said doped semiconductor layer, wherein said intrinsic semiconductor layer is an intrinsic portion of said contiguous P-I-N junction.

39. The photovoltaic structure of claim 30, wherein nanowires in said array of nanowires have a vertical dimension from 1 micron to 100 micron.

40. The photovoltaic structure of claim 30, wherein nanowires in said array of nanowires have a maximum lateral dimension from 5 nm to 1,000 nm.

41. The photovoltaic structure of claim 30, wherein said dopes semiconductor material is doped with aluminum.

42. The photovoltaic structure of claim 30, wherein said silicon layer includes amorphous hydrogenated silicon or polycrystalline hydrogenated silicon.

43. The photovoltaic structure of claim 30, wherein said silicon layer includes single crystalline silicon.

44. The photovoltaic structure of claim 30, further comprising a conductive metal layer contacting said silicon layer

45. The photovoltaic structure of claim 30, further comprising a conductive material layer contacting said doped semiconductor material.
